(19) United States
(12) Patent Application Publication
(10) Pub. No.: US 2023/0326824 A1
(43) Pub. Date: Oct. 12, 2023

(54) DUAL-SIDED MOLDED PACKAGE WITH EXPOSED BACKSIDE DIE FOR THERMAL DISSIPATION

(71) Applicant: Skyworks Solutions, Inc., Irvine, CA (US)

(72) Inventor: Howard E. Chen, Anaheim, CA (US)

(21) Appl. No.: 18/297,971

(22) Filed: Apr. 10, 2023

Related U.S. Application Data
(60) Provisional application No. 63/362,814, filed on Apr. 11, 2022.

(51) Int. Cl. H01L 23/367; H01L 23/498; H01L 23/31; H01L 23/00; H01L 25/16; H01L 23/552; H01L 21/56

(52) U.S. Cl. CPC H01L 23/367; H01L 23/49811; H01L 23/3121; H01L 2224/32225; H01L 25/165; H01L 23/552; H01L 21/56; H01L 24/32

(57) ABSTRACT

A dual-sided molded package module has a substrate, and a die and multiple posts attached to a bottom side of the substrate. A bottom mold surrounds and extends between the posts and the die. Electrically and thermally conductive interconnect members are attached to the posts and extend through the bottom mold. A thermally conductive layer is attached to a bottom facing surface of the die. The thermally conductive layer extends through the mold and couples to a motherboard (e.g., via solder material) so that the thermally conductive layer can dissipate heat from the die to the motherboard.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of this disclosure relate to packaging of circuit devices, such as radio frequency modules that can be mounted on a circuit board, and more particularly to dual-sided molded packages of circuit devices with exposed backside die for thermal dissipation.

### Description of the Related Art

Circuit devices, such as radio frequency modules, can be implemented in a packaged module. Such devices can be connected to a mother board (e.g., of an electronic device) via solder balls. Some packaged modules are dual sided (e.g., have dies on a top side and a bottom side), which results in increased heat generated from the operation of the bottom die that is directed to the substrate for dissipation.

### SUMMARY

The innovations described in the claims each have several aspects, no single one of which is solely responsible for its desirable attributes. Without limiting the scope of the claims, some prominent features of this disclosure will now be briefly described.

In accordance with one aspect of the disclosure, a dual-sided molded package module is provided with improved thermal dissipation of the backside die (e.g., die on a bottom side of the substrate of the module).

In accordance with one aspect of the disclosure, a dual-sided molded package module is provided with improved thermal dissipation of the backside die (e.g., die on a bottom side of the substrate of the module). Heat from the backside die is dissipated directly to the motherboard via a thermally conductive material disposed on the backside die that interconnects the die and the motherboard.

In some aspects of the disclosure, a dual-sided molded package module is provided. The dual-sided molded package module includes a substrate having a top side and an opposite bottom side. A die is attached to the bottom side of the substrate, and a plurality of posts are attached to the bottom side of the substrate and are laterally spaced from the die. A bottom mold surrounds and extends between the plurality of posts and the die. A plurality of electrically and thermally conductive interconnect members are attached to the plurality of posts and extend through the bottom mold. A thermally conductive layer is attached a bottom facing surface of the die, the thermally conductive layer extending through the mold and configured to couple to a motherboard. The thermally conductive layer is configured to dissipate heat from the die to the motherboard.

In some aspects of the disclosure, a wireless device is provided. The wireless device includes a motherboard and a dual-sided molded package module mounted on the motherboard. The dual-sided molded package module includes a substrate having a top side and an opposite bottom side, a die attached to the bottom side of the substrate, and a plurality of posts attached to the bottom side of the substrate and being laterally spaced from the die. A bottom mold surrounds and extends between the plurality of posts and the die. A plurality of electrically and thermally conductive interconnect members are attached to the plurality of posts and extend through the bottom mold. A thermally conductive layer are attached a bottom facing surface of the die, the thermally conductive layer extending through the mold and coupled to the motherboard. The thermally conductive layer is configured to dissipate heat from the die to the motherboard.

In some aspects of the disclosure, a method of making a dual-sided molded package module is provided. The method includes the steps of forming or providing a substrate having a top side and an opposite bottom side, forming or providing a plurality of posts attached to the bottom side of the substrate, attaching a die to the bottom side of the substrate, and forming or providing a bottom mold over the posts and the die. The method also includes the steps of removing at least a portion of the bottom mold to expose the posts and a bottom facing surface of the die, forming or applying a thermally conductive material over the posts and the bottom facing surface of the die, and removing at least a portion of the thermally conductive material to form a plurality of electrically and thermally conductive interconnect members attached to the plurality of posts and a thermally conductive layer attached to the bottom facing surface of the die. The thermally conductive layer is separated from the electrically and thermally conductive interconnect members by the bottom mold.

### BRIEF DESCRIPTION OF THE DRAWINGS

Embodiments of this disclosure will now be described, by way of non-limiting example, with reference to the accompanying drawings.

FIG. 1 is a schematic view of an existing dual-sided package module with various electronic components.

FIG. 2 is a schematic view of a dual-sided molded package module with improved thermal dissipation.

FIG. 2A is a schematic view of the dual-sided molded package module spaced above a motherboard on which the module is mounted.

FIG. 3A is a schematic view of an intermediate configuration in forming the dual-sided molded package module of FIG. 2.

FIG. 3B is a schematic view of an intermediate configuration in forming the dual-sided molded package module of FIG. 2.

FIG. 3C is a schematic view of an intermediate configuration in forming the dual-sided molded package module of FIG. 2.

FIG. 3D is a schematic view of an intermediate configuration in forming the dual-sided molded package module of FIG. 2.

FIG. 4 shows a process for forming the dual-sided molded package module of FIG. 2.

FIG. 5 shows a process for forming the dual-sided molded package module of FIG. 2.

FIG. 6 shows one or more of modules that are mounted on a wireless phone board that can include one or more features described herein.

FIG. 7 schematically depicts the circuit board with the shielded wafer level chip scale package installed thereon.

FIG. 8 schematically depicts a wireless device having the circuit board with the shielded wafer level chip scale package installed thereon.

FIG. 9 is a schematic diagram of one example of a communication network.

FIG. 10 is a schematic diagram of one embodiment of a mobile device.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

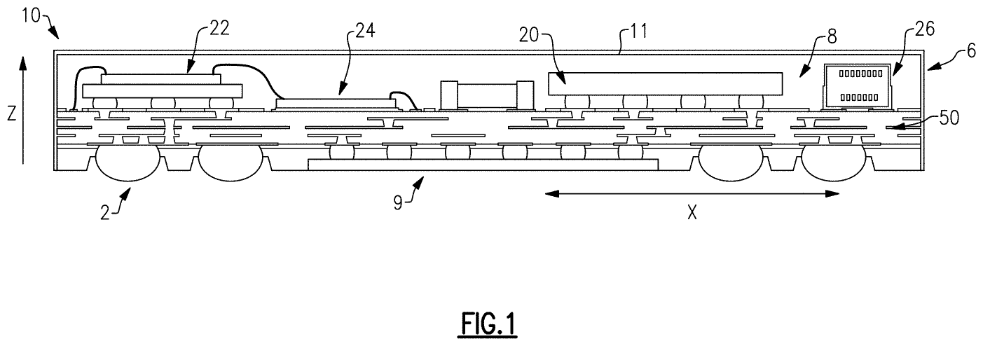

FIG. 1 shows a dual-sided molded package module 10 with one or more (a plurality of) solder connections (e.g., balls, or other electrical interconnect members) 2 that are connected to an underside of a printed circuit board (PCB) 50. A plurality of electronic components 6 are connected to a top side of the PCB 50, including a wafer level chip scale package (WLCSP) 20, a flip stack 22, a die 24 and a surface mount technology (SMT) package 26. Wirebonds can connect different components. A top mold 8 (e.g., overmold) can be disposed over the electronic components 6. A die 9 (e.g., backside die) is disposed on an underside of the PCB 50. A shield 11 is disposed over the top mold 8 to shield all of the electronic components 6 from electromagnetic (EM) interference from components outside the shield 11. The package 10 can be mounted on a phone board or motherboard of an electronic device.

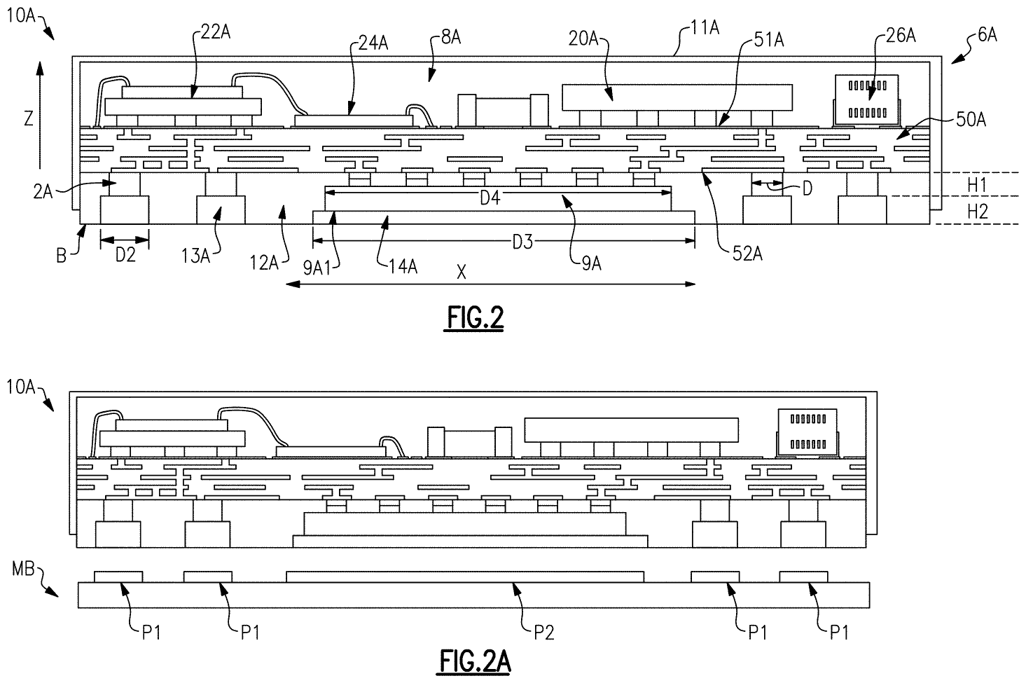

FIG. 2 shows a dual-sided molded package module 10A. Some of the features of the dual-sided molded package module 10A are similar to features of the dual-sided molded package module 10 in FIG. 1. Thus, reference numerals used to designate the various components of the dual-sided molded package module 10A are identical to those used for identifying the corresponding components of the dual-sided molded package module 10 in FIG. 1, except that an “A” has been added to the numerical identifier. Therefore, the structure and description for the various features of the dual-sided molded package module 10 in FIG. 1 are understood to also apply to the corresponding features of the dual-sided molded package module 10A in FIG. 2, except as described below.

The dual-sided molded package module 10A differs from the dual-sided molded package module 10 in that posts 2A are attached to a bottom side 52A of the substrate 50A (instead of solder balls 2 in FIG. 1). In one implementation, the posts 2A can have a circular cross-section. However, the posts 2A can have other suitable cross-sectional shapes (e.g., square). The posts 2A can be made of a thermally and electrically conductive material (e.g., metal, solder material). Each post 2A has a lateral dimension D (e.g., width, diameter) and height H1. Other electronic components 6A can be mounted to a top side 51A of the substrate 50A.

An electrically and thermally conductive interconnect member 13A can be attached to each post 2A. In one implementation, the interconnect member 13A can have the same cross-sectional shape as the post 2A (e.g., circular, square). The interconnect members 13A are made of an electrically and thermally conductive material (e.g., copper). The interconnect member 13A has a lateral dimension D2 (e.g., width, diameter), in the X direction, and height H2, in the Z direction transverse to the X direction. The lateral dimension D2 of the interconnect member 13A is greater than the lateral dimension D of the post 2A. In one implementation, the height H2 of the interconnect member 13A is approximately equal to the height H1 of the post 2A. In another implementation, the height H2 of the interconnect member 13A is greater than the height H1 of the post 2A.

A layer 14A of thermally conductive material is disposed on a bottom facing surface 9A1 of the die 9A (e.g., backside die). The layer 14A can be made of the same material as the interconnect members 13A (e.g., a thermally conductive material, such as copper). The layer 14A can extend over a lateral dimension D3 (e.g., width and/or depth) that is greater than a lateral dimension D4 (e.g., width) of the die 9A. The layer 14A can extend over the entire bottom facing surface 9A1 of the die 9A. In another implementation, where the die 9A has a through wafer via (TWV), the layer 14A can be excluded or can only extend over the location of the via to dissipate heat from the die 9A with the layer 14A and through wafer via (TWV).

A bottom mold 12A is disposed on the bottom side 52A of the substrate 50A so that it surrounds and extends between the posts 2A and interconnect members 13A, as well as surrounds and extends between the die 9A and the posts 2A and interconnect members 13A. The interconnect members 13A and layer 14A can extend through the bottom mold 12A so that the bottom surface B of the module 10A is defined by the interconnect members 13A, the layer 14A and the bottom mold 12A that extends between an laterally surrounds (in the X direction) the interconnect members 13A and the layer 14A.

In one implementation, the material of the interconnect members 13A and layer 14A is a solderable material (e.g., has a solderable finish) and does not oxidize. In another implementation, a solderable material can be applied to the interconnect members 13A and layer 14A, via which the module 10A can be mounted to a motherboard MB (see FIG. 2A) via pads P1, P2. Advantageously, the layer 14A allows (e.g. facilitates) dissipation of heat from the die 9A directly to the motherboard MB that the module 10A is coupled to, rather than via the substrate 50A.

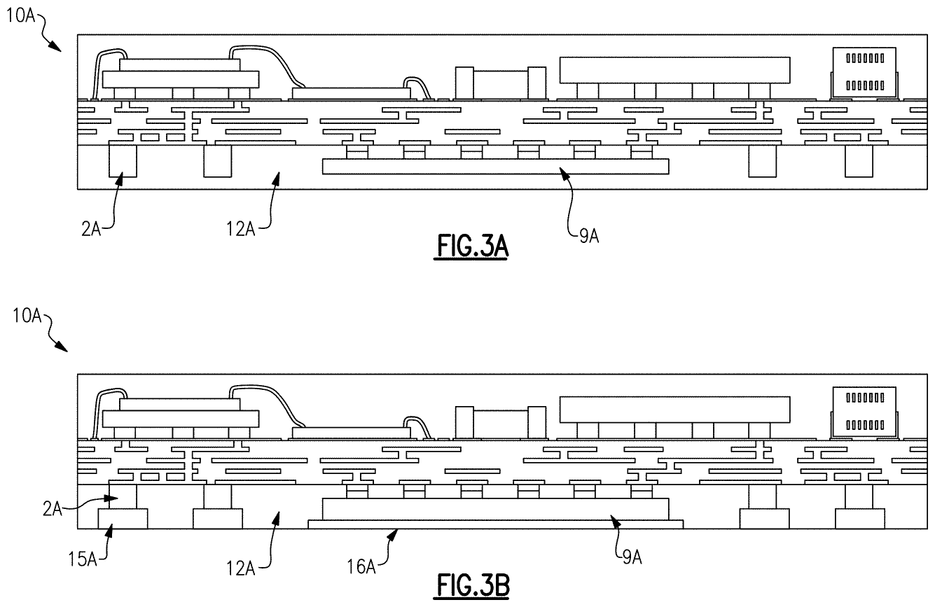

FIGS. 3A-3D show intermediate configurations during manufacture of the dual-sided molded package module 10A of FIG. 2. FIG. 3A shows the posts 2A attached to the bottom side 52A of the substrate 50A. The posts 2A can be formed or deposited on the bottom side 52A (e.g., attached to a plurality of pads—not shown-on the bottom side 52A). The bottom mold 12A is formed or provided over the bottom side 52A of the substrate so that it surrounds and covers the posts 2A and the die 9A (e.g., backside die).

FIG. 3B shows that a portion of the bottom mold 12A is removed to expose the posts 2A (e.g., expose a bottom side of the posts 2A). Recesses 15A (e.g., open cavities) are created in the bottom mold 12A that are aligned with the posts 2A. In one implementation, the recesses 15A are formed via laser ablation. However, other suitable processes and mechanisms can be used to form the recesses 15A. The recesses 15A can have a lateral dimension (e.g., diameter, width), in the X direction, that is greater than the lateral dimension D of the posts 2A. The recesses 15A can have a height that in one implementation can be approximately the same as the height of the post 2A. In another implementation, the recesses 15A can have a height that is greater than the height of the post 2A. With continue reference to FIG. 3B, a portion of the bottom mold 12A is removed under the die 9A to expose the bottom facing surface 9A1 of the die 9A, creating a recess 16A in the bottom mold 12A under the die 9A. The recess 16 can extend across the entire area of the die 9A. In one implementation, the recess 16 can have a lateral dimension (e.g., width, depth, in the X direction, that is greater than the lateral dimension D4 of the die 9A. In another implementation, the recess 16 can have a lateral dimension approximately equal to the lateral dimension D4 of the die 9A.

FIG. 3C shows the depositing of a thermally conductive material 17A into the recesses 15A, 16A and over a bottom of the module 10A so that it covers the bottom mold 12A. The thermally conductive material 17A can be applied via a sputtering process. However, other suitable mechanisms or processes for depositing or forming the thermally conductive material under the die 9A and posts 2A can be used. FIG. 3D shows the removal of the thermally conductive material 17A to expose the mold 12A and define the interconnect members 13A and layer 14A that extend through the bottom mold 12A (e.g., the bottom surface B of the module 10A is defined by the interconnect members 13A, the layer 14A and the bottom mold 12A that extends between an laterally surrounds—in the X direction—the interconnect members 13A and the layer 14A).

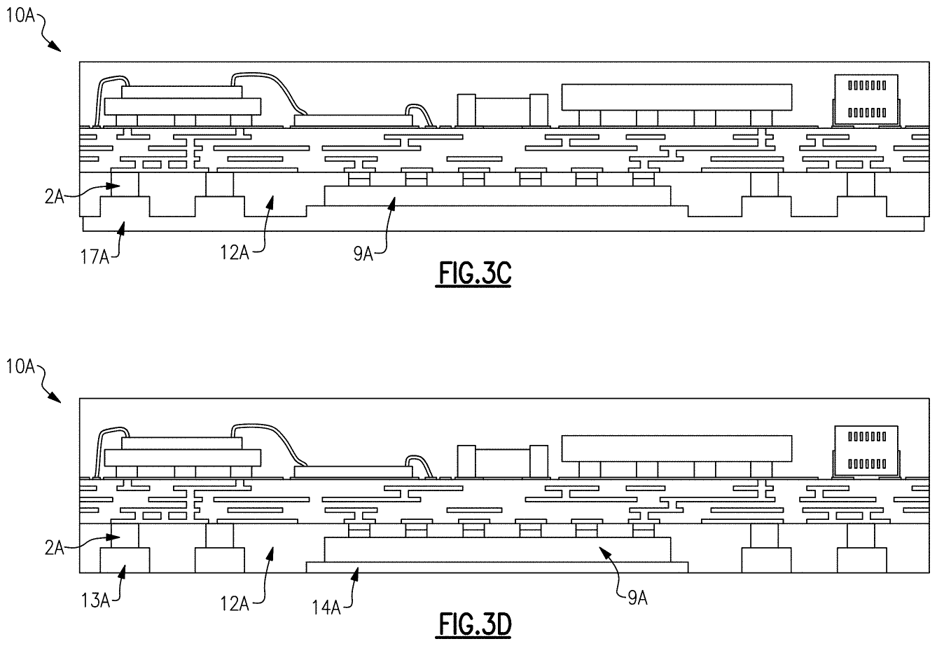

FIG. 4 shows a method 30 for forming the dual-sided molded package module 10A of FIG. 2. The method 30 includes forming or providing 52 conductive posts (e.g., posts 2A) on a bottom side (e.g., bottom side 52A) of a substrate (e.g., substrate 50A). In one implementation, the posts are preformed with the substrate. In another implementation, the posts (e.g., posts 2A) can be formed or provided using surface mount technology (SMT). The method 30 also includes the step of forming or providing 34 a bottom mold (e.g., bottom mold 12A) over the bottom side of the substrate to cover the posts (and a die attached to the bottom side of the substrate). The method 30 also includes the step of removing 36 at least a portion of the bottom mold (e.g., bottom mold 12A), for example via laser ablation, to expose the posts and bottom surface of the die (e.g., creating recesses in the bottom mold under the posts and die). The method 30 also includes the step of forming or providing 38 an electrically and thermally conductive material in strip form under the posts and die (e.g., to define a bottom side of the module and cove the bottom mold). The method 30 also includes removing 40 (e.g., by grinding) at least a portion of the electrically and thermally conductive material (e.g., of layers of the material) to expose the bottom mold and define interconnect members attached to the posts and a layer under the die. The method 30 also includes the step of forming or providing 42 a shield over a top mold (e.g., overmold) that covers electronics on a top side of the substrate.

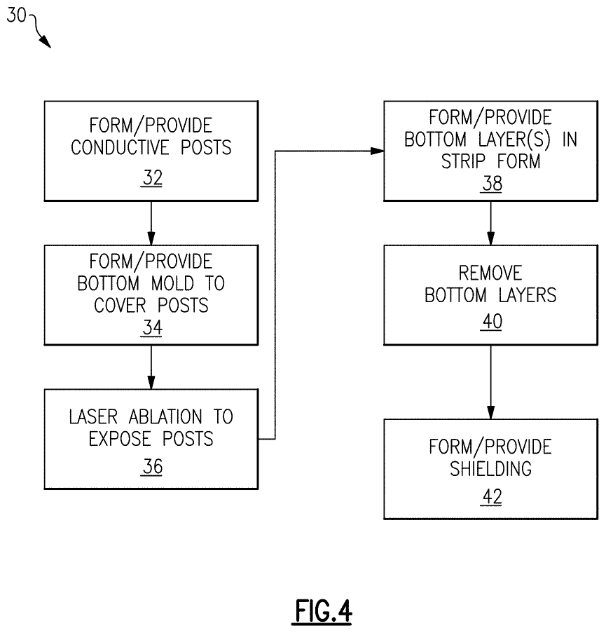

FIG. 5 shows a method 50 for forming the dual-sided molded package module 10A of FIG. 2. The method is similar to the method 30, so that the same description above applies to the same steps illustrated in FIG. 5. The method 50 differs from the method 30 in that following the step of removing at least a portion of the electrically and thermally conductive material, it includes the step of forming or applying 62, for example via screen printing, a solder material to the interconnect members and/or layer of thermally conductive material attached to the die.

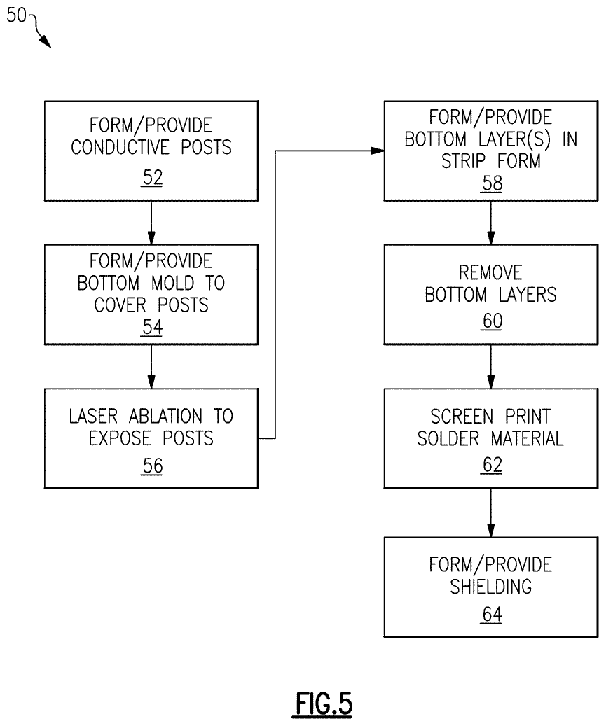

FIG. 6 shows that in some embodiments, one or more modules included in a circuit board such as a wireless phone board can include one or more of the dual sided molded package module 10A of FIG. 2, as described herein. Non-limiting examples of modules that can benefit from such packaging features include, but are not limited to, a controller module, an application processor module, an audio module, a display interface module, a memory module, a digital baseband processor module, a global positioning system (GPS) module, an accelerometer module, a power management module, a transceiver module, a switching module, and a power amplifier module.

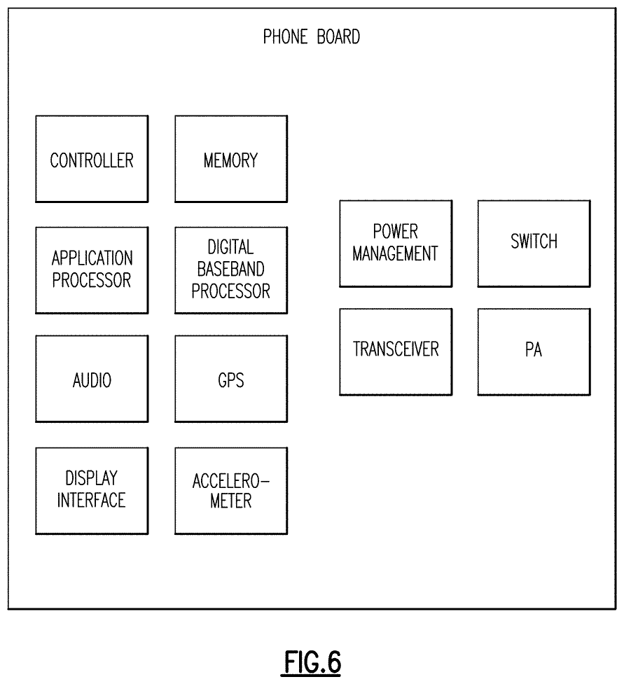

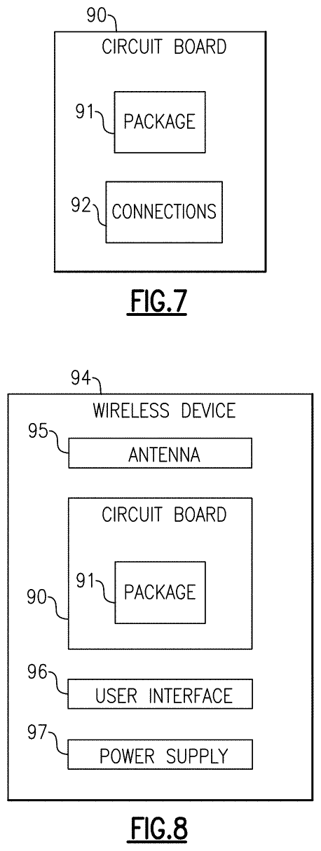

FIG. 7 schematically depicts a circuit board 90 having a package (e.g., die, SMT package, filter) 91 mounted thereon in the manner described herein (e.g., the package 91 can be a dual sided molded package module 10A of FIG. 2). The circuit board 90 can also include other features such as a plurality of connections 92 to facilitate operations of various packages mounted thereon. FIG. 8 schematically depicts a wireless device 94 (e.g., a cellular phone) having a circuit board 90 (e.g., a phone board). The circuit board 90 is shown to include a package (e.g., die, SMT package, filter) 91 mounted thereon in the manner described herein (e.g., the package 91 can be a dual sided molded package module * of FIG. 2). The wireless device is shown to further include other components, such as an antenna 95, a user interface 96, and a power supply 97.

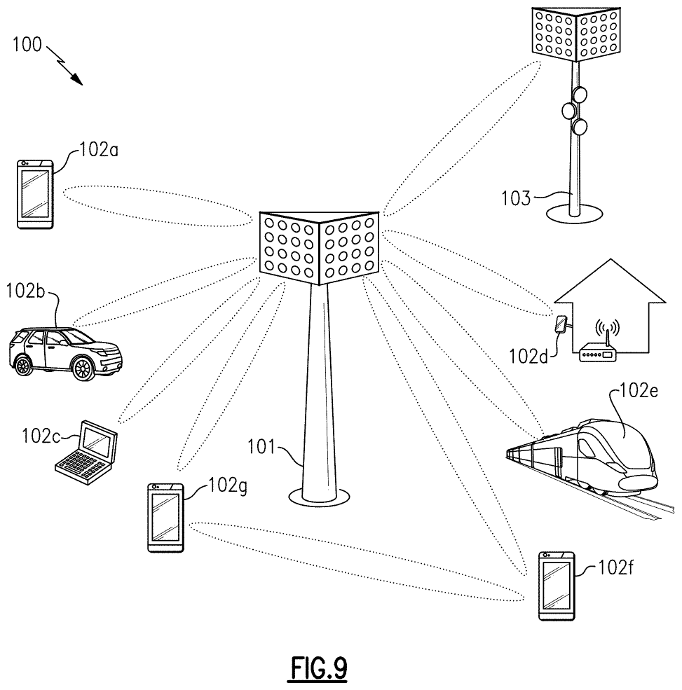

FIG. 9 is a schematic diagram of one example of a communication network 100. The communication network 100 includes a macro cell base station 101, a small cell base station 103, and various examples of user equipment (UE), including a first mobile device 102a, a wireless-connected car 102b, a laptop 102c, a stationary wireless device 102d, a wireless-connected train 102e, a second mobile device 102f, and a third mobile device 102g.

Although specific examples of base stations and user equipment are illustrated in FIG. 9, a communication network can include base stations and user equipment of a wide variety of types and/or numbers.

For instance, in the example shown, the communication network 100 includes the macro cell base station 101 and the small cell base station 103. The small cell base station 103 can operate with relatively lower power, shorter range, and/or with fewer concurrent users relative to the macro cell base station 101. The small cell base station 103 can also be referred to as a femtocell, a picocell, or a microcell. Although the communication network 100 is illustrated as including two base stations, the communication network 100 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 100 of FIG. 9 supports communications using a variety of cellular technologies, including, for example, 4G LTE and 5G NR. In certain implementations, the communication network 100 is further adapted to provide a wireless local area network (WLAN), such as WiFi. Although various examples of communication technologies have been provided, the communication network 100 can be adapted to support a wide variety of communication technologies.

Various communication links of the communication network 100 have been depicted in FIG. 9. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 9, the communication links include not only communication links between UE and base stations, but also UE to UE communications and base station to base station communications. For example, the communication network 100 can be implemented to support self-fronthaul and/or self-backhaul (for instance, as between mobile device 102g and mobile device 102f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1) in the range of about 410 MHz to about 7.125 GHz, Frequency Range 2 (FR2) in the range of about 24.250 GHz to about 52.600 GHz, or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 100 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 100 of FIG. 9 can be used to support a wide variety of advanced communication features, including, but not limited to, eMBB, uRLLC, and/or mMTC.

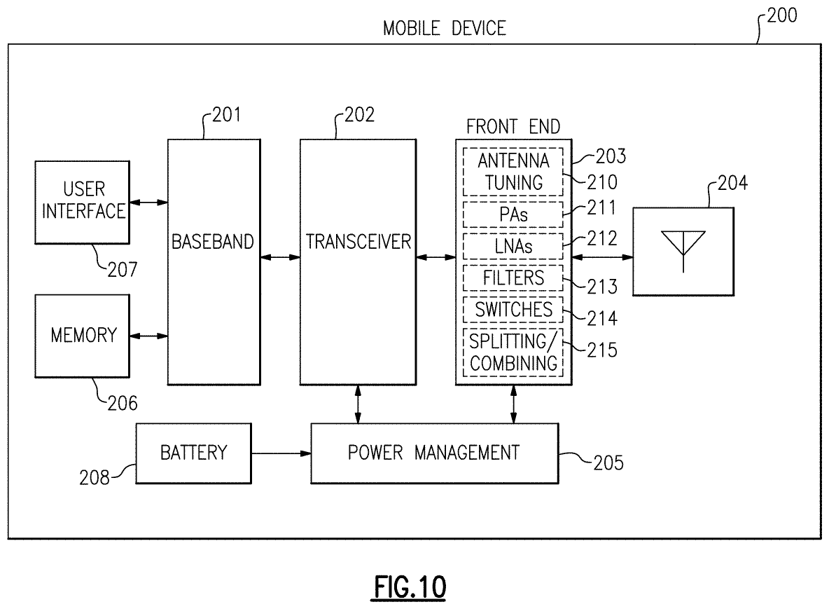

FIG. 10 is a schematic diagram of one embodiment of a mobile device 200. The mobile device 200 includes a baseband system 201, a transceiver 202, a front end system 203, antennas 204, a power management system 205, a memory 206, a user interface 207, and a battery 208.

The mobile device 200 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 202 generates RF signals for transmission and processes incoming RF signals received from the antennas 204. It will be understood that various functionalities associated with the transmission and receiving of RF signals can be achieved by one or more components that are collectively represented in FIG. 10 as the transceiver 202. In one example, separate components (for instance, separate circuits or dies) can be provided for handling certain types of RF signals.

The front end system 203 aids in conditioning signals transmitted to and/or received from the antennas 204. In the illustrated embodiment, the front end system 203 includes antenna tuning circuitry 210, power amplifiers (PAs) 211, low noise amplifiers (LNAs) 212, filters 213, switches 214, and signal splitting/combining circuitry 215. However, other implementations are possible.

For example, the front end system 203 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 200 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 204 can include antennas used for a wide variety of types of communications. For example, the antennas 204 can include antennas for transmitting and/or receiving signals associated with a wide variety of frequencies and communications standards.

In certain implementations, the antennas 204 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 200 can operate with beamforming in certain implementations. For example, the front end system 203 can include amplifiers having controllable gain and phase shifters having controllable phase to provide beam formation and directivity for transmission and/or reception of signals using the antennas 204. For example, in the context of signal transmission, the amplitude and phases of the transmit signals provided to the antennas 204 are controlled such that radiated signals from the antennas 204 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 204 from a particular direction. In certain implementations, the antennas 204 include one or more arrays of antenna elements to enhance beamforming.

The baseband system 201 is coupled to the user interface 207 to facilitate processing of various user input and output (I/O), such as voice and data. The baseband system 201 provides the transceiver 202 with digital representations of transmit signals, which the transceiver 202 processes to generate RF signals for transmission. The baseband system 201 also processes digital representations of received signals provided by the transceiver 202. As shown in FIG. 10, the baseband system 201 is coupled to the memory 206 of facilitate operation of the mobile device 200.

The memory 206 can be used for a wide variety of purposes, such as storing data and/or instructions to facilitate the operation of the mobile device 200 and/or to provide storage of user information.

The power management system 205 provides a number of power management functions of the mobile device 200. In certain implementations, the power management system 205 includes a PA supply control circuit that controls the supply voltages of the power amplifiers 211. For example, the power management system 205 can be configured to change the supply voltage(s) provided to one or more of the power amplifiers 211 to improve efficiency, such as power added efficiency (PAE).

As shown in FIG. 10, the power management system 205 receives a battery voltage from the battery 208. The battery 208 can be any suitable battery for use in the mobile device 200, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kilohertz (kHz) to 300 gigahertz (GHz), such as in a frequency range from about 450 MHz to 8.5 GHz. An acoustic wave resonator including any suitable combination of features disclosed herein be included in a filter arranged to filter a radio frequency signal in a fifth generation (5G) New Radio (NR) operating band within Frequency Range 1 (FR1). A filter arranged to filter a radio frequency signal in a 5G NR operating band can include one or more acoustic wave resonators disclosed herein. FR1 can be from 410 MHz to 7.125 GHz, for example, as specified in a current 5G NR specification. One or more acoustic wave resonators in accordance with any suitable principles and advantages disclosed herein can be included in a filter arranged to filter a radio frequency signal in a fourth generation (4G) Long Term Evolution (LTE) operating band and/or in a filter with a passband that spans a 4G LTE operating band and a 5G NR operating band.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Any of the embodiments described above can be implemented in association with mobile devices such as cellular handsets. The principles and advantages of the embodiments can be used for any systems or apparatus, such as any uplink cellular device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals having a frequency in a range from about 30 kHz to 300 GHz, such as a frequency in a range from about 450 MHz to 8.5 GHz.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A dual-sided molded package module comprising:
a substrate having a top side and an opposite bottom side;
a die attached to the bottom side of the substrate;
a plurality of posts attached to the bottom side of the substrate and being laterally spaced from the die;
a bottom mold surrounding and extending between the plurality of posts and the die;
a plurality of electrically and thermally conductive interconnect members attached to the plurality of posts and extending through the bottom mold; and
a thermally conductive layer attached a bottom facing surface of the die, the thermally conductive layer extending through the mold and configured to couple to a motherboard, the thermally conductive layer configured to dissipate heat from the die to the motherboard.

2. The dual-sided molded package module of claim 1 wherein the thermally conductive layer extends across an entire bottom facing surface of the die.

3. The dual-sided molded package module of claim 1 wherein the electrically and thermally conductive interconnect members are made of a same material as the thermally conductive layer.

4. The dual-sided molded package module of claim 1 wherein the thermally conductive layer is separated from the electrically and thermally conductive interconnect members by the bottom mold.

5. The dual-sided molded package module of claim 1 wherein the electrically and thermally conductive interconnect members have a greater lateral dimension than the posts.

6. The dual-sided molded package module of claim 1 further including one or more electronic components connected to the top side of the substrate and a top mold disposed over the electronic components.

7. The dual-sided molded package module of claim 6 further including a shield disposed over the top mold and a side of the substrate.

8. A wireless device comprising:
a motherboard; and
a dual-sided molded package module mounted on the motherboard, the dual-sided molded package module including a substrate having a top side and an opposite bottom side, a die attached to the bottom side of the substrate, a plurality of posts attached to the bottom side of the substrate and being laterally spaced from the die, a bottom mold surrounding and extending between the plurality of posts and the die, a plurality of electrically and thermally conductive interconnect members attached to the plurality of posts and extending through the bottom mold, and a thermally conductive layer attached a bottom facing surface of the die, the thermally conductive layer extending through the mold and coupled to the motherboard, the thermally conductive layer is configured to dissipate heat from the die to the motherboard.

9. The wireless device of claim 8 wherein the thermally conductive layer is coupled to the motherboard via a solderable material attached to the thermally conductive layer.

10. The wireless device of claim 8 wherein the thermally conductive layer extends across an entire bottom facing surface of the die.

11. The wireless device of claim 8 wherein the electrically and thermally conductive interconnect members are made of a same material as the thermally conductive layer.

12. The wireless device of claim 8 wherein the thermally conductive layer is separated from the electrically and thermally conductive interconnect members by the bottom mold.

13. The wireless device of claim 8 wherein the electrically and thermally conductive interconnect members have a greater lateral dimension than the posts.

14. The wireless device of claim 8 further including one or more electronic components connected to the top side of the substrate and a top mold disposed over the electronic components.

15. The wireless device of claim 14 further including a shield disposed over the top mold and a side of the substrate.

16. A method of manufacturing a dual-sided molded package module comprising:
forming or providing a substrate having a top side and an opposite bottom side;
forming or providing a plurality of posts attached to the bottom side of the substrate;
attaching a die to the bottom side of the substrate;
forming or providing a bottom mold over the posts and the die;
removing at least a portion of the bottom mold to expose the posts and a bottom facing surface of the die;
forming or applying a thermally conductive material over the posts and the bottom facing surface of the die; and
removing at least a portion of the thermally conductive material to form a plurality of electrically and thermally conductive interconnect members attached to the plurality of posts and a thermally conductive layer attached to the bottom facing surface of the die, the thermally conductive layer separated from the electrically and thermally conductive interconnect members by the bottom mold.

17. The method of claim 16 further including forming or providing solder connections over the electrically and thermally conductive interconnect members and the thermally conductive layer.

18. The method of claim 17 wherein said removing at least a portion of the bottom mold to expose the posts and a bottom facing surface of the die includes laser ablation of the bottom mold.

19. The method of claim 18 wherein the laser ablation creates recesses in the bottom mold with a greater lateral dimension than the posts.

20. The method of claim 17 wherein removing at least a portion of the thermally conductive material includes grinding the thermally conductive material.
